(19) United States
(12) Patent Application Publication
(10) Pub. No.: US 2017/0133327 A1
(43) Pub. Date: May 11, 2017

(54) ELECTRIC MODULE COMPRISING A TENSIONING DEVICE

(71) Applicant: SIEMENS AKTIENGESELLSCHAFT, MUENCHEN (DE)

(72) Inventors: DANIEL SCHMITT, NUERNBERG (DE); ANDREAS ZENKNER, OBERMICHELBACH (DE)

(21) Appl. No.: 15/127,484

(22) PCT Filed: Mar. 20, 2014
(86) PCT No.: PCT/EP2014/055623

§ 371 Date: Sep. 20, 2016

(51) Int. Cl. H01L 23/00; H01L 21/54; H01L 25/065; H01L 21/48; H01L 23/053; H01L 23/20

(52) U.S. Cl. CPC H01L 23/562; H01L 23/053; H01L 23/20; H01L 25/0657; H01L 21/4817; H01L 21/54; H01L 2225/06589

(57) ABSTRACT

An electrical module includes at least one electrical component and at least one hollow body which is filled or can be filled with a medium, particularly a fluid. The hollow body exerts a pressing force, dependent on the prevailing internal pressure in the interior of the hollow body, onto the at least one component of the module. A method for clamping an electrical module is also provided.

The invention relates to electrical modules having electrical components, in particular component stacks, wherein a clamping force is generated in order to produce a clamping arrangement.

Electrical modules having component stacks are known by way of example in the field of multilevel convertors.

Multilevel convertors are described for example in the conference paper “An Innovative Modular Multilevel Converter Topology suitable for a Wide Power Range” (Anton Lesnicar and Rainer Marquardt, 2003 IEEE Bologna Power Tech Conference, June 23^{rd}-26^{th}, Bologna, Italy).

In order in the case of components that are stacked one on top of the other or in the case of component stacks to generate the clamping forces that are required to produce the mechanical clamping arrangement, threaded systems are used nowadays in combination with plate springs or other resilient elements that introduce a mechanical force into the mechanical system. However, the clamping force is generally introduced in a very point-by-point manner using one or more screw elements by way of pressure pieces so that it is not always possible to achieve a homogenous distribution of the clamping force over a large area. It is very difficult particularly for very large semiconductor elements to achieve a homogenous distribution of the clamping force over the entire semiconductor surface using the known point-by-point mechanical thread systems.

The object of the invention is accordingly to provide an electrical module which renders it possible to generate a clamping force for clamping the module in a manner that requires a very little expenditure and is also very homogenous over the module surface.

This object is achieved in accordance with the invention by means of an electrical module having the features in accordance with patent claim 1. Advantageous embodiments of the module in accordance with the invention are disclosed in the subordinate claims.

Accordingly, it is provided in accordance with the invention that the electrical module comprises at least one hollow body that is filled or can be filled with a medium, in particular a fluid and said hollow body exerts a pressing force on at least one component of the module, said pressing force being dependent upon its internal pressure prevailing in the interior of the hollow body.

An essential advantage of the module in accordance with the invention resides in the fact that a homogenous pressing force for clamping the module can be generated with very little expenditure; it is sufficient to fill the hollow body and to increase the internal pressure of said hollow body. The pressure that is generated as a result is at least almost homogenous over the entire cross-sectional area of the hollow body.

It is particularly cost effective if the hollow body is formed by means of a bladder or a balloon, the size of which is dependent upon the pressure. The hollow body is preferably expandable and preferably comprises an elastic deformable material (e.g. synthetic material or rubber);

alternatively, the shell of the hollow body is also embodied from a material that is slightly or not at all expandable, such as by way of example a metal foil.

With regard to a homogenous distribution of pressing force in the interior of the module, it is considered advantageous if the size of the cross-sectional area of the hollow body—viewed in the cross section in a transverse manner with respect to the longitudinal direction of the module—corresponds to the cross-sectional area of the component.

In order to achieve a dual function of the hollow body, namely on the one hand the function of generating a pressing force and on the other hand the function of a providing a damping action, it is considered advantageous if the medium can be compressed. In an advantageous manner, the medium is a gas, in particular air. In other words, it is therefore advantageous if the hollow body forms a gas pressure spring that as a component of a clamping device that clamps the module exerts a resilient force on the at least one component of the module.

The module can comprise by way of example a component stack that comprises two or more components. In the case of such an embodiment, it is advantageous if the hollow body forms a component of a clamping device that presses the component stack together.

If the module comprises two or more hollow bodies then it is advantageous if the hollow bodies are connected to one another in terms of pressure. A connection in terms of pressure simplifies on the one hand the procedure of filling the hollow body; on the other hand it is rendered possible by means of the connection in terms of pressure to form a pressure spring clamping system that grips over the module and resiliently clamps the module by gripping over said module.

With regard to the arrangement of the hollow bodies, it is considered as advantageous if at least one of the hollow bodies is arranged outside the component stack and exerts from outside a pressing force on the component stack. In an advantageous manner, the hollow body that is arranged outside the component stack is arranged in a receiving container that forms a counter bearing and said receiving container comprises in the direction towards the component stack a container aperture by means of which the hollow body exerts its pressing force on the component stack.

It is considered to be particularly advantageous if the module comprises at least two hollow bodies, namely a first hollow body that is arranged on a first stack end of the component stack and that exerts from outside a pressing force on the first stack end, and a second hollow body that is arranged on a second stack end of the component stack and that exerts from outside a pressing force on the second stack end.

In the case of the latter variant, it is particularly advantageous if the first hollow body that is arranged outside the component stack is arranged in a first receiving container that forms a first counter bearing and said first receiving container comprises a container aperture that is facing the first stack end of the component stack and by means of said container aperture the first hollow body exerts its pressing force on the first stack end of the component stack, and the second hollow body that is arranged outside the component stack is arranged in a second receiving container that forms a second counter bearing and said second receiving container comprises a container aperture that is facing the second stack end of the component stack and by means of said container aperture the second hollow body exerts its pressing force on the second stack end of the component stack.

With regard to producing an optimum damping of the components of the component stack, in particular in the case of an internal explosion of components of the module, it is considered advantageous if at least one of the hollow bodies lies in the interior of the component stack, divides the component stack to form stack segments and exerts a pressing force on the stack segments that lie against said hollow body, said pressing force being dependent upon its internal pressure.

The component stack comprises as components preferably semiconductor components, in particular semiconductor elements and/or rectifier elements, cooling bodies and/or connection electrodes.

The invention further relates to a method for clamping at least one electrical module that comprises a component.

With regard to generating a homogenous as possible clamping force, it is considered advantageous if at least one hollow body of a clamping device of the module is filled with a fluid until the hollow body exerts a predetermined minimum pressing force directly or indirectly on the component.

With regard to the advantages of the method in accordance with the invention, reference is made to the above statements in connection with the module in accordance with the invention since the advantages of the module in accordance with the invention correspond essentially to those of the method in accordance with the invention.

The invention is further explained hereinunder with reference to exemplary embodiments; in the drawings by way of example:

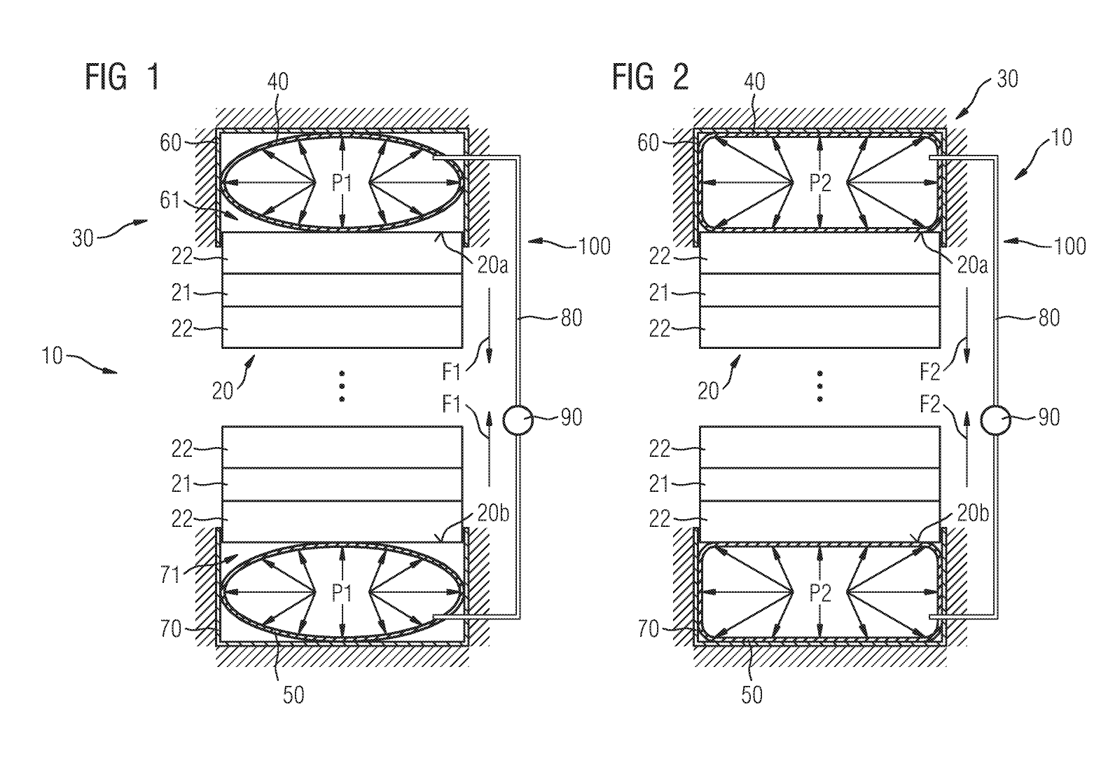

FIG. 1 illustrates an exemplary embodiment for an electrical module, wherein a clamping device comprises two gas-filled hollow bodies, wherein the hollow bodies are illustrated in FIG. 1 with an average gas pressure,

FIG. 2 illustrates the electrical module in accordance with FIG. 1, after the gas pressure in the hollow bodies has been increased,

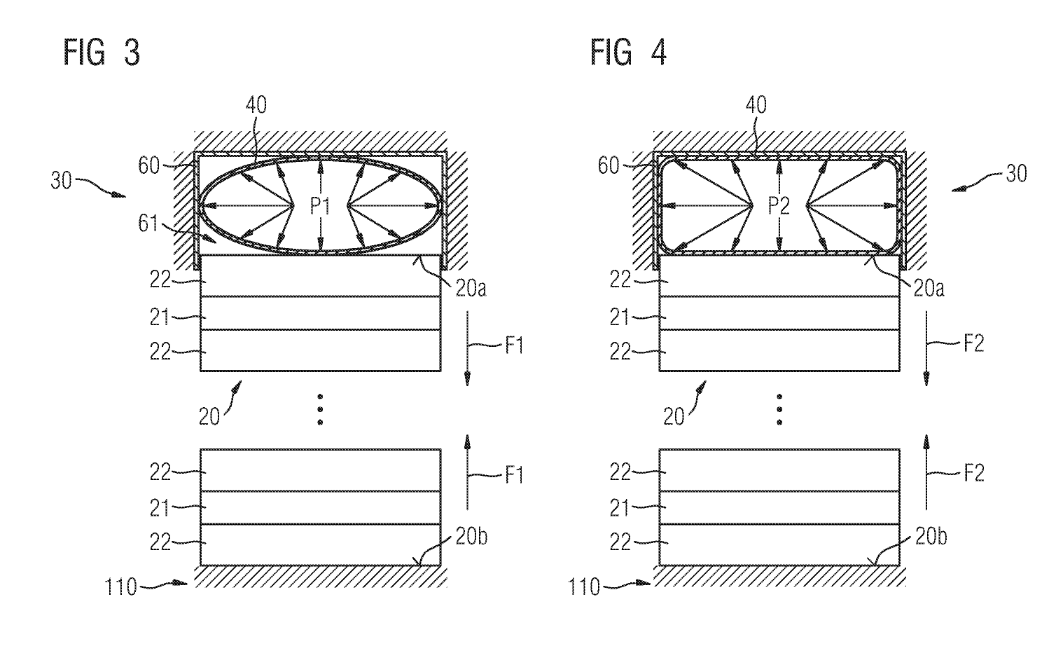

FIG. 3 illustrates an exemplary embodiment for an electrical module, wherein a clamping device comprises a single gas-filled hollow body for clamping the module, wherein the FIG. 3 illustrates the hollow body with an average gas pressure,

FIG. 4 illustrates the electrical module in accordance with FIG. 3, after the gas pressure in the hollow body has been increased,

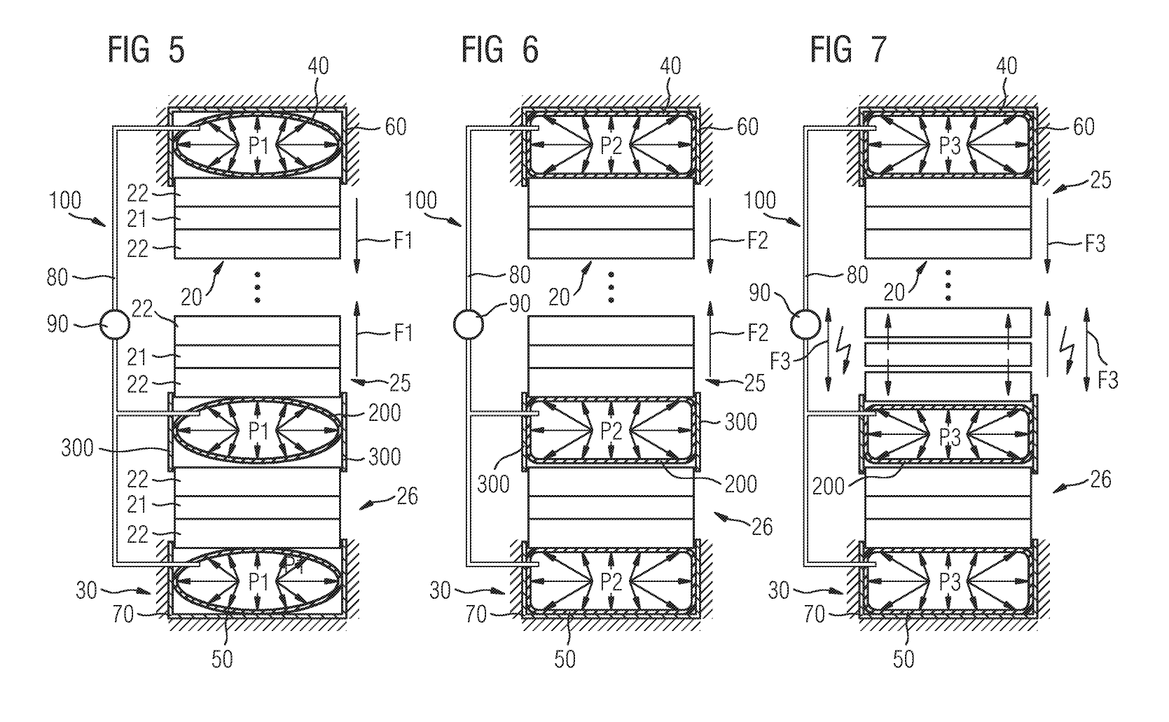

FIG. 5 illustrates an exemplary embodiment for an electrical module, wherein a clamping device comprises two outer gas-filled hollow bodies and in addition an inner-lying gas-filled hollow body, wherein FIG. 5 illustrates an average gas pressure of the three hollow bodies,

FIG. 6 illustrates the electrical module in accordance with FIG. 5 after the gas pressure in the three hollow bodies has been increased, and

FIG. 7 illustrates the behavior of the electrical module in accordance with FIG. 6 in the event of an electrical malfunction and an explosion that is occurring in the interior of the module.

For the sake of clarity, identical or comparable components are always provided with identical reference numerals in the figures.

FIG. 1 illustrates an electrical module 10 that is equipped with a component stack 20. The component stack 20 comprises a plurality of components, of which FIG. 1 illustrates semiconductor components and cooling bodies identified by the reference numerals 21 and 22. For the purposes of pressing together the components of the component stack 20, the electrical module 10 is equipped with a clamping device 30 that forms a clamped unit.

The clamping device 30 comprises a first expandable hollow body 40 and a second expandable hollow body 50. The two expandable hollow bodies 40 and 50 can be formed by way of example by bladders or expandable balloons.

The first hollow body 40, illustrated at the top in FIG. 1, is held in a first receiving container 60 that is fixedly mounted in place and forms a counter bearing for the hollow body 40. The first receiving container 60 comprises a container aperture 61 by means of which the hollow body 40 can exert a pressing force on a stack end 20a of the component stack 20, said stack end being the upper stack in FIG. 1 and referred to hereinunder as the first stack end.

The second hollow body 50 is located in a second receiving container 70 that is likewise fixedly mounted in place and forms a counter bearing for the second hollow body 50. The second hollow body 50 is connected by means of a container aperture 71 of the receiving container 70 to a second stack end 20b of the component stack 20, said second stack being illustrated at the bottom in FIG. 1.

The two hollow bodies 40 and 50 are coupled in terms of pressure by way of a pressure line 80 and can be filled by way of a valve 90 with a medium, by way of example a compressible medium, such as air. The two hollow bodies 40 and 50, the pressure line 80 and the valve 90 form a pressure spring clamping system 100 of the clamping device 30 or of the electrical module 10, said pressure spring clamping system being gas-tight with respect to the outside and—as a result of the pressure line 80—pressure-coupled.

FIG. 1 illustrates the two hollow bodies 40 and 50 in the case of an average gas pressure P1, wherein although the two hollow bodies 40 and 50 lie against the two stack ends 20a and 20b of the component stack 20, only a small pressing force F1 is exerted on the component stack 20.

In order to press the component stack 20 together or to clamp the module 10, the pressure spring clamping system 100 is filled with gas by way of the valve 90 and the internal pressure in the two hollow bodies 40 and 50 is increased. By virtue of increasing the internal pressure, the two hollow bodies 40 and 50 expand, as is illustrated in FIG. 2. It is evident that the two hollow bodies 40 and 50 completely fill the allocated receiving container 60 and 70 and the contact pressure against the two stack ends 20a and 20b of the component stack 20 is significantly increased. The pressing force on the two stack ends 20a and 20b is identified in the FIG. 2 by the reference numeral F2.

By virtue of increasing the pressure in the interior of the two hollow bodies 40 and 50, a clamping force is generated, as a result of which the components of the component stack 20 are pressed together and the electrical contact resistance between the components of the component stack 20 is reduced.

FIG. 3 illustrates an exemplary embodiment for an electrical module 10 whose component stack 20 can correspond to the component stack of the electrical module 10 in accordance with FIGS. 1 and 2. Accordingly, the component stack 20 also comprises in accordance with FIG. 3 semiconductor components 21 and cooling bodies 22.

In order to clamp the component stack 20, a clamping device 30 is provided in the case of the electrical module 10 and said clamping device 30 comprises only a single expandable hollow body 40. The hollow body 40 is held in a receiving container that forms a counter bearing and by virtue of the container aperture 61 of said receiving container 60 the hollow body 40 lies on the stack end 20a of the component stack 20, said stack end being the upper stack end in FIG. 3.

The second stack end 20b of the component stack 20, said second stack end being illustrated at the bottom in FIG. 3, lies on a counter bearing 110 that is fixed in place.

FIG. 3 illustrates the electrical module 10 in the case of an average gas pressure in the interior of the hollow body 40. It is evident that although the hollow body 40 lies on the first stack end 20a of the component stack 20, the contact pressure by means of the hollow body 40 is still low. The contact pressure or pressuring force is identified in FIG. 3 by the reference numeral F1.

FIG. 4 illustrates the electrical module 10 after the gas pressure in the interior of the hollow body 40 has been increased so that the hollow body 40 completely fills the allocated receiving container 60 and exerts a significant pressing force F2 on the component stack 20 by way of the container aperture 61. The following therefore applies:

F2>>F1.

By virtue of filling the hollow body 40 and generating the pressing force F2, the components of the component stack 20 are pressed together so that the electrical contact resistance between the components of the component stack 20 is minimized.

FIG. 5 illustrates an exemplary embodiment for an electrical module, wherein a component stack 20 comprises a plurality of semiconductor components 21 and a plurality of cooling bodies 22. In order to clamp the component stack 20 or to clamp the module 10, a clamping device 30 is provided that comprises two outer expandable hollow bodies 40 and 50 and also a hollow body 200 that is lying inside or in the interior of the component stack 20. The two outer hollow bodies 40 and 50 are held in the receiving containers 60 and 70 that form in each case counter bearings for the clamping device 30. The hollow bodies 40 and 50 and also the receiving container 60 and 70 can correspond to the hollow bodies and receiving containers in accordance with FIGS. 1 and 2, so that reference is made to the above statements regarding said hollow bodies and receiving containers.

The two hollow bodies 40 and 50 and also the inner-lying hollow body 200 are connected to one another in terms of pressure by way of a pressure line 80 and can be filled with gas by way of a valve 90. The three hollow bodies 40, 50 and 200, the pressure line 80 and the valve 90 form a pressure spring clamping system 10 that is gas-tight with respect to the outside and—as a result of the pressure line 80—pressure-coupled, said pressure spring clamping system 100 rendering it possible to press together or clamp the component stack 20.

By means of the inner-lying hollow body 200, the component stack 20 is subdivided into two stack segments 25 and 26. The stack segments 25 and 26 can be electrically isolated from one another by means of the inner-lying hollow body 200. Alternatively, it is possible to connect the two stack segments 25 and 26 in an electrical manner to one another and to provide for this purpose conducting plates with which the electrical connection is produced. Electrical plates of this type are indicated by way of example in FIG. 5 and are identified by the reference numeral 300. The plates 300 are not only able to provide an electrical function for connecting the stack segments 25 and 26 but rather in addition also form a lateral delimitation for the hollow body 200 by means of which the lateral expansion of the hollow body 200 in a perpendicular manner with respect to the longitudinal direction of the component stack 20 in the event of an increase in pressure is reduced.

FIG. 5 illustrates the pressure spring clamping system 100 or the three hollow bodies 40, 50 and 200 in the case of an average gas pressure P1, wherein the component stack 20 is pressed together with an only small pressing force F1.

FIG. 6 illustrates the electrical module 10 in accordance with FIG. 5 after an increase in pressure P2 in the interior of the three hollow bodies 40, 50 and 200 has resulted in a significant increase in the pressing force that is acting on the component stack 20. The increased pressing force is identified in FIG. 6 by the reference numeral F2. The following therefore applies:

F2>>F1 and P2>>P1.

By virtue of the pressure increase in the interior of the hollow body 40, 50 and 200 and by the increase in the pressing force on the component stack 20, the components of the component stack 20 are pressed together so that the contact resistance between the components is minimized.

FIG. 7 illustrates the manner in which the three hollow bodies 40, 50 and 200 operate or function in the event of one or more of the components of the component stack 20 malfunctioning and an explosion occurring. The pressure wave that occurs as a result of the explosion and is symbolized in FIG. 7 by means of a pressure P3 and a pressing force F3 is absorbed completely or at least in part by the hollow bodies 40, 50 and 200 that are connected to one another in terms of pressure. The hollow body 40, 50 and 200 function so to say as shock absorbers by means of which the mechanical forces that are acting on the other, non-exploded and still functioning components of the component stack 20 are moderated or reduced. It is thus possible in an advantageous manner by means of the hollow bodies 40, 50 and 200 of the pressure spring clamping system 100, said hollow bodies functioning as gas pressure springs, to avoid the mechanical destruction of the other, non-exploded components of the component stack 20 whilst the clamped unit remains sufficiently rigid and also does not or does not significantly open during a malfunction event.

The fact that a gap is not formed also means that electric arcs are not formed. Consequential damages are to a great extent prevented.

Although the invention has been further illustrated and described in detail with reference to preferred exemplary embodiments the invention is not limited by means of the disclosed examples and other variations can be derived therefrom by the person skilled in the art without departing from the protective scope of the invention.

### LIST OF REFERENCE NUMERALS

10 Electrical module
20 Component stack
20a First stack end
20b Second stack end
21 Semiconductor component
22 Cooling body
25 Stack segment
26 Stack segment
30 Clamping device
40 First hollow body
50 Second hollow body
60 First receiving container
61 Container aperture
70 Second receiving container
71 Container aperture
80 Pressure line
90 Valve
100 Pressure spring clamping system
110 Counter bearing
200 Inner-lying hollow body
300 Electrical plate
F1 Pressing force/contact pressure
F2 Pressing force/contact pressure
F3 Pressing force/contact pressure
P1 Gas pressure
P2 Gas pressure
P3 Gas pressure

1-14. (canceled)

15. an electrical module, comprising:
at least one electrical component;
at least one hollow body having an interior being filled or being configured to be filled with a medium;
said at least one hollow body exerting a pressing force on said at least one electrical component; and
said pressing force being dependent upon an internal pressure prevailing in said interior of said at least one hollow body.

16. The module according to claim 15, wherein said medium is a fluid.

17. The module according to claim 15, wherein said at least one hollow body is formed by a bladder or a balloon having a size being dependent upon said internal pressure.

18. The module according to claim 15, wherein:
said at least one electrical component has a cross-sectional area;
the module has a longitudinal direction;
said at least one hollow body has a cross-sectional area with a size transverse to the longitudinal direction of the module; and
said size of said cross-sectional area of said at least one hollow body corresponds to said cross-sectional area of said at least one electrical component.

19. The module according to claim 15, wherein:
said medium is a compressible gas; and
said at least one hollow body forms a gas pressure spring being a component of a clamping device clamping the module and exerting a resilient force on said at least one component.

20. The module according to claim 18, wherein said compressible gas is air.

21. The module according to claim 15, wherein:
said at least one electrical component includes two or more electrical components in at least one component stack; and
said at least one hollow body forms a component of a clamping device pressing said component stack together.

22. The module according to claim 15, wherein said at least one hollow body includes two or more hollow bodies being in communication with one another in terms of pressure.

23. The module according to claim 22, wherein said two or more hollow bodies being in communication with one another in terms of pressure form a pressure-tight pressure spring clamping system resiliently clamping the module.

24. The module according to claim 21, wherein said at least one hollow body is disposed outside said component stack and exerts a pressing force on said component stack from outside.

25. The module according to claim 24, which further comprises:
a receiving container receiving said at least one hollow body disposed outside said component stack;
said receiving container forming a counter bearing and said receiving container having a container aperture in a direction towards said component stack through which said at least one hollow body exerts said pressing force on said component stack.

26. The module according to claim 21, wherein:
said component stack has a first stack end and a second stack end;
said at least one hollow body includes a first hollow body disposed on said first stack end and exerting a pressing force on said first stack end from outside; and
said at least one hollow body includes a second hollow body disposed on said second stack end and exerting a pressing force on said second stack end from outside.

27. The module according to claim 26, which further comprises:
a first receiving container receiving said first hollow body disposed outside said component stack, said first receiving container forming a first counter bearing and said first receiving container including a container aperture facing said first stack end, said first hollow body exerting said pressing force through said container aperture on said first stack end of said component stack; and
a second receiving container receiving said second hollow body disposed outside said component stack, said second receiving container forming a second counter bearing and said second receiving container including a container aperture facing said second stack end of said component stack, said second hollow body exerting said pressing force through said container aperture on said second stack end of said component stack.

28. The module according to claim 21, wherein said component stack has an interior, and said at least one hollow body lies in said interior of said component stack, divides said component stack to form stack segments and exerts a pressing force on said stack segments lying against said component stack.

29. The module according to claim 21, wherein said component stack includes components selected from the group consisting of semiconductor components, semiconductor elements, rectifier elements, cooling bodies and connection electrodes.

30. A method for clamping an electrical module having at least one component, the method comprising the following step:
filling at least one hollow body of a clamping device of the module with a fluid until the at least one hollow body exerts a predetermined minimum pressing force directly or indirectly on the at least one component.
